(19) United States
(12) Patent Application Publication
(10) Pub. No.: US 2026/0245624 A1
(43) Pub. Date: Aug. 20, 2026

(54) PROGRAM REFRESH FOR NON-VOLATILE MEMORY ARRAY IN A SEMICONDUCTOR DEVICE

(71) Applicant: Silicon Storage Technology, Inc., San Jose, CA (US)

(72) Inventor: Hieu Van Tran, San Jose, CA (US)

(21) Appl. No.: 19/253,559

(22) Filed: Jun. 27, 2025

Related U.S. Application Data
(60) Provisional application No. 63/761,141, filed on Feb. 20, 2025.

(51) Int. Cl. G11C 16/10; G11C 14/00; G11C 16/04; G11C 16/26

(52) U.S. Cl. CPC G11C 16/10; G11C 16/0425; G11C 16/26; G11C 14/00

(57) ABSTRACT

Programming technique for a semiconductor device having a plurality of tiles of non-volatile memory cells, an alternative tile of non-volatile memory cells, and a reference memory cell. The technique includes programming the reference memory cell to a target program state corresponding to a reference read current or to reference threshold voltage, and determining through a read operation on the reference memory cell that a read current is above the reference read current by at least a current deviation amount or that a threshold voltage is below the reference threshold voltage by at least a voltage deviation amount. In response to the determining, first data is read from a first one of the plurality of tiles, the first data is stored in the alternative tile, and one or more pulses of programming voltages are applied to the first one of the plurality of tiles.

### RELATED APPLICATIONS

This application claims the benefit of U.S. Provisional Application No. 63/761,141, filed Feb. 20, 2025, and which is incorporated herein by reference.

### FIELD OF THE INVENTION

The present invention relates to non-volatile memory cells of semiconductor devices, and more particularly to an array configuration and method for performing program refresh operations.

### BACKGROUND OF THE INVENTION

Split-gate non-volatile memory semiconductor devices are well known in the art. See for example U.S. Pat. No. 7,868,375, which discloses a four-gate memory cell configuration, and which is incorporated herein by reference for all purposes. Specifically, FIG. 1 of the present disclosure illustrates a pair of split gate non-volatile memory cells 10 each with spaced apart source and drain regions 14/16 formed in a silicon semiconductor substrate 12. The source region 14 can be referred to as a source line SL (because it commonly is connected to other source regions for other non-volatile memory cells 10 in the same row or column), and the drain region 16 is commonly connected to a bit line. A channel region 18 of the substrate 12 extends between the source/drain regions 14/16. A floating gate 20 is disposed over (i.e., vertically over and laterally overlapping) and insulated from (and directly controls the conductivity of) a first portion of the channel region 18 (and partially over, and insulated from, the source region 14). A control gate 22 is disposed over, and insulated from, the floating gate 20. A select gate 24 (also referred to as a word line gate) is disposed over, and insulated from, and directly controls the conductivity of, a second portion of the channel region 18. An erase gate 26 is disposed over and insulated from the source region 14 and is laterally adjacent to the floating gate 20. The erase gate 26 can include a notch that faces an edge of the floating gate 20.

A plurality of such memory cells 10 can be arranged in rows and columns to form a memory cell array, as illustrated in FIG. 2. While FIG. 1 only shows a pair of memory cells 10 (sharing a common source region 14 and erase gate 26), the memory cell pairs can be placed end to end to form a column of memory cells 10 (where the memory cell pairs can share a common drain region 16). While only two such columns are shown in FIG. 2, there can be many such columns. Each column can include a bit line 16a electrically connecting together all the drain regions 16 in the column. Each row of memory cells 10 can include a control gate line 22a electrically connecting together all the control gates 22 in the row of memory cells 10. For example, all the control gates 22 in each row of memory cells 10 can be formed as a continuous line of conductive material, where a portion of the continuous line passing through any given memory cell 10 serves as its control gate 22. Each row of memory cells 10 can include a select gate line 24a electrically connecting together all the select gates 24 in the row of memory cells 10. For example, all the select gates 24 in each row of memory cells 10 can be formed as a continuous line of conductive material, where a portion of the continuous line passing through any given memory cell 10 serves as its select gate 24. Each row of memory cell pairs can include an erase gate line 26a electrically connecting together all the erase gates 26 in the row of memory cell pairs. For example, all the erase gates 26 in each row of memory cell pairs can be formed as a continuous line of conductive material, where a portion of the continuous line passing through any given memory cell pair serves as its erase gate 26. Finally, each row of memory cell pairs can include a source line 14a electrically connecting together all the source regions 14 in the row of memory cell pairs. For example, all the source regions 14 in each row of memory cell pairs can be formed as a continuous line of conductive diffusion in the substrate 12, where a portion of the continuous line passing through any given memory cell pair serves as its source region 14.

Various combinations of voltages are applied to the control gate 22, select gate 24, erase gate 26 and source and drain regions 14/16, to program the split gate non-volatile memory cell 10 (i.e., inject electrons onto the floating gate 20), to erase the split gate non-volatile memory cell 10 (i.e., remove electrons from the floating gate 20), and to read the split gate non-volatile memory cell 10 (i.e., measure or detect the conductivity of the channel region 18 in a read operation, by for example measuring or detecting a read current Ir through the channel region 18 or determine from the read current Ir the threshold voltage, which a voltage applied to one of the gates of the memory cell necessary to yield a sufficient read current Ir through the channel region, to determine the program state of the floating gate 20).

Split gate non-volatile memory cell 10 can be operated in a digital manner, where the split gate non-volatile memory cell 10 is set to one of only two possible states: a programmed state and an erased state. The split gate non-volatile memory cell 10 is erased by placing a high positive voltage on the erase gate 26, and optionally a negative voltage on the control gate 22, to induce tunneling of electrons from the floating gate 20 to the erase gate 26 (leaving the floating gate 20 in a more positively charged state—the erased state). Split gate non-volatile memory cell 10 can be programmed by placing positive voltages on the control gate 22, erase gate 26, select gate 24 and source region 14, and a current on drain region 16. Electrons will then flow along the channel region 18 from the drain region 16 toward the source region 14, with electrons becoming accelerated and heated whereby some of them are injected onto the floating gate 20 by hot-electron injection (leaving the floating gate 20 in a more negatively charged state—the programmed state).

Split gate non-volatile memory cell 10 can be read by placing positive voltages on the select gate 24 (turning on the portion of channel region 18 under the select gate 24 by making it conductive) and drain region 16 (and optionally on the erase gate 26 and the control gate 22), and sensing current flow (i.e., read current Ir) through the channel region 18 (i.e., read current Ir is the current flowing through the channel region 18 during a read operation). If the floating gate 20 is positively charged (i.e. split gate non-volatile memory cell 10 is erased), the split gate non-volatile memory cell 10 will turn on because the both portions of the channel region 18 are conductive due to the lack of electrons on the floating gate 20, and electrical current will flow from drain region 16 to source region 14 (i.e. the split gate non-volatile memory cell 10 is sensed to be in its erased “1” state based on sensed current flow). If the floating gate 20 is negatively charged (i.e. split gate non-volatile memory cell 10 is programmed), the portion of channel region 18 under the floating gate is turned off (low conductivity), thereby preventing appreciable current flow (i.e., the split gate non-volatile memory cell 10 is sensed to be in its programmed “0” state based on no, or minimal, current flow). Memory cells 10 are considered non-volatile because they maintain their program state even when power is not applied to the semiconductor device. Memory cells 10 can be referred to as split gate non-volatile memory cells because two different gates (floating gate 20 and select gate 24), respectively, directly control the conductivity of two different portions of the channel region 18.

Table 1 below provides non-limiting examples of the voltages that can be used to perform the read, erase and program operations on the memory cell 10 of FIG. 1.

TABLE 1

| Operation | SG 24 | Drain 16 | CG 22 | EG 26 | Source 14 |
|---|---|---|---|---|---|
| Read | 1.0-2 V | 0.6-2 V | 0-2.6 V | 0-2.6 V | 0 V |
| Erase | −0.5 V or 0 | 0 V | 0 V or −8 | 8-12 V | 0 V |
| | V | | V | | |
| Program | 1 V | ~0.3 V | 8-11 V | 4.5-9 V | 4.5-5 V |
| | | (1 uA) | | | |

One technique to program the memory cells 10 is sequential programming, which involves applying the programming voltages as a series of pulses, with each pulse of programming voltages injecting more electrons onto the floating gate thus increasing the program state of the memory cell 10 with each pulse, until the desired program state (also referred to as the target program state) is achieved (i.e., until the target read current for the target program state is achieved). With sequential programming, there can be intervening read operations between the pulses of programming voltages to determine if the target program state has been achieved by the last applied programming pulse (in which case programming ceases) or has not been achieved (in which case programming continues with one or more programming pulses). For example, each target program state can be associated with a target read current Irtarget (i.e., the desired and therefore target current through the channel region 18 during a read operation that is associated with the target program state). Alternately or additionally, each target program state can be associated with a target threshold voltage, which is the voltage applied to one of the gates of the memory cell necessary to achieve a threshold read current. The higher the program state (i.e., the more electrons on the floating gate), the lower the read current Ir and the higher the threshold voltage. The lower the program state (i.e., the fewer electrons on the floating gate), the higher the read current Ir and the lower the threshold voltage. Therefore, read current Ir will drop and threshold voltage will rise after each pulse of programming voltages. Once a target read current Irtarget or a target threshold voltage is reached (reflecting the desired or target program state), programming for that memory cell 10 ceases.

If the same set of program voltages are applied during each pulse in sequential programming, the programming amount drops pulse to pulse, because as the floating gate becomes more negatively charged with each pulse, fewer electrons are injected onto the floating gate if the parameters of the programming pulses (applied voltages, supplied current, duration) remain constant. Therefore, when a memory cell 10 is determined to have not reached its target program state after any given pulse, one or more of the programming parameters can be stepped up to a higher value in the next pulse, to compensate for the dropping pulse-to-pulse programming amount that would otherwise occur. For example, for the memory cell 10 of FIG. 1, programming parameters that can be stepped up from one programming pulse to the next programming pulse can include increases in one or more of the following: voltage applied to the control gate, voltage applied to the erase gate, voltage applied to the source region, current supplied to the drain region, and duration of the programming pulse.

Split gate non-volatile memory cell 10 can alternately be operated in an analog manner where the program state (i.e. the amount of charge, such as the number of electrons, on the floating gate 20) of the split gate-non-volatile memory cell 10 can be incrementally changed anywhere from a fully erased state (minimum number of electrons on the floating gate 20) to a fully programmed state (maximum number of electrons on the floating gate 20), or just a portion of this range. This means the split gate non-volatile memory cell 10 storage is analog, which allows for very precise and individual tuning of each split gate non-volatile memory cell 10 in an array of split gate non-volatile memory cells 10. Alternatively, the split gate non-volatile memory cell 10 could be operated as an MLC (multilevel cell) where it is configured to be programmed to one of many discrete values (such as 16 or 64 different values).

Split gate non-volatile memory cells with fewer gates are also known. For example, FIG. 3 illustrates known split gate non-volatile memory cells 10 that are the same as that of FIG. 1, except the control gates 22 are omitted. See for example U.S. Pat. No. 7,315,056, which is incorporated herein by reference for all purposes. Voltage coupling to the floating gate 20 provided by the control gate 22 of the split gate non-volatile memory cell 10 of FIG. 1 is provided instead by the erase gate 26 and source region 14 of the split gate non-volatile memory cell 10 in FIG. 3. FIG. 4 illustrates an example layout of an array of the split gate non-volatile memory cells 10 of FIG. 3. Table 2 below provides non-limiting examples of the voltages that can be used to perform the read, erase and program operations on the memory cell 10 of FIG. 3.

TABLE 2

| Operation | SG 24 | Drain 16 | EG 26 | Source 14 |
|---|---|---|---|---|
| Read | 0.7-2.2 V | 0.6-2 V | 0-2.6 V | 0 V |
| Erase | −0.5 v or 0 V | 0 V | 11.5 V | 0 V |
| Program | 1 V | ~0.3 V | 4.5-9 V | 7-9 V |
| | | (2-3 uA) | | |

As another example, FIG. 5 illustrates known split gate non-volatile memory cells 10 that are similar to that of FIG. 1, except the control gates 22 and the erase gates 26 are omitted. See for example U.S. Pat. No. 5,029,130, which is incorporated herein by reference for all purposes. The erase voltage for the split gate non-volatile memory cell 10 of FIG. 5 is applied to the select gate 24, which has a first portion laterally adjacent the floating gate 20, and a second portion that extends up and over the floating gate 20. FIG. 6 illustrates an example layout of an array of the split gate non-volatile memory cells 10 of FIG. 5. Table 3 below provides non-limiting examples of the voltages that can be used to perform the read, erase and program operations on the memory cell 10 of FIG. 5.

TABLE 3

| Operation | SG 24 | Drain 16 | Source 14 |
|---|---|---|---|
| Read | 2-3 V | 0.6-2 V | 0 V |
| Erase | 11-13 V | 0 V | 0 V |
| Program | 1-2 V | ~0.3 V (1-3 uA) | 9-10 V |

As yet another example, FIG. 7 illustrates known split gate non-volatile memory cells 10 that are similar to that of FIG. 5, except a conductive block of material 28 is formed in contact with source region 14, to serve as an extended source line. See for example U.S. U.S. Pat. No. 6,855,980, which is incorporated herein by reference for all purposes. An example layout for an array of the split gate non-volatile memory cells 10 of FIG. 7 can be the same as that in FIG. 6.

One issue with split gate non-volatile memory cells 10 is charge loss, where after programming, the threshold voltage Vth drops and the read current Icell increases over time. One source of charge loss is leakage of electrons off of the floating gate. Another source of charge loss is electrons trapped in the dielectric materials around the floating gate become detrapped and move away from the floating gate. If the magnitude of charge loss becomes excessive, it can cause a read error by making the memory cell appear to be programmed in a lower program state during a read operation. There is a need to reduce the number of such read errors when charge loss occurs.

### BRIEF SUMMARY OF THE INVENTION

The aforementioned problems and needs are addressed by a method of programming a semiconductor device that comprises a plurality of tiles of non-volatile memory cells, an alternative tile of non-volatile memory cells, and a reference memory cell. The method comprises programming the reference memory cell to a target program state that corresponds to a reference read current of the reference memory cell or a reference threshold voltage of the reference memory cell, determining through a read operation on the reference memory cell that a read current of the reference memory cell is above the reference read current by at least a current deviation amount or that a threshold voltage of the reference memory cell is below the reference threshold voltage by at least a voltage deviation amount, in response to the determining, reading first data from a first one of the plurality of tiles of non-volatile memory cells, storing the first data in the alternative tile of non-volatile memory cells, and applying one or more pulses of programming voltages to the first one of the plurality of tiles of non-volatile memory cells.

A semiconductor device comprises a plurality of tiles of non-volatile memory cells, an alternative tile of non-volatile memory cells, a reference memory cell, and a control circuitry to, program the reference memory cell to a target program state that corresponds to a reference read current of the reference memory cell or a reference threshold voltage of the reference memory cell, determine through a read operation on the reference memory cell that a read current of the reference memory cell is above the reference read current by at least a current deviation amount or that a threshold voltage of the reference memory cell is below the reference threshold voltage by at least a voltage deviation amount, in response to the determination, read first data from a first one of the plurality of tiles of non-volatile memory cells, store the first data in the alternative tile of non-volatile memory cells, and apply one or more pulses of programming voltages to the first one of the plurality of tiles of non-volatile memory cells.

A method of programming a semiconductor device that comprises a plurality of tiles of non-volatile memory cells and an alternative tile of non-volatile memory cells. The method comprising determining a specific period of time has elapsed, in response to the determining, reading first data from a first one of the plurality of tiles of non-volatile memory cells, storing the first data in the alternative tile of non-volatile memory cells, and applying one or more pulses of programming voltages to the first one of the plurality of tiles of non-volatile memory cells.

A semiconductor device comprises a plurality of tiles of non-volatile memory cells, an alternative tile of non-volatile memory cells, and a control circuitry to determine a specific period of time has elapsed, in response to the determination, read first data from a first one of the plurality of tiles of non-volatile memory cells, store the first data in the alternative tile of non-volatile memory cells, and apply one or more pulses of programming voltages to the first one of the plurality of tiles of non-volatile memory cells.

Other objects and features of the present disclosure will become apparent by a review of the specification, claims and appended figures.

### BRIEF DESCRIPTION OF THE DRAWINGS

FIG. 1 is a cross sectional view of a conventional pair of memory cells.

FIG. 2 is a schematic and layout diagram of a conventional memory cell array of the memory cells of FIG. 1.

FIG. 3 is a side cross sectional view of a conventional pair of memory cells.

FIG. 4 is a schematic and layout diagram of a conventional memory cell array of the memory cells of FIG. 3.

FIG. 5 is a side cross sectional view of a conventional pair of memory cells.

FIG. 6 is a schematic and layout diagram of a conventional memory cell array of the memory cells of FIG. 5.

FIG. 7 is a side cross sectional view of a conventional pair of memory cells.

FIG. 8 is a diagram illustrating components of a semiconductor device.

FIG. 9 is a schematic and layout diagram of a portion of the semiconductor device.

FIG. 10 is a flow diagram illustrating an example of a refresh programming method for the semiconductor device of FIG. 9.

FIG. 11 is a schematic and layout diagram of a portion of the semiconductor device.

FIG. 12 is a flow diagram illustrating an example of a refresh programming method for the semiconductor device of FIG. 11.

FIG. 13 is a schematic and layout diagram of a portion of the semiconductor device.

FIG. 14 is a schematic and layout diagram of a portion of the semiconductor device.

FIG. 15 is a flow diagram illustrating an example of a refresh programming method.

FIG. 16 is a flow diagram illustrating an example of a refresh programming method.

### DETAILED DESCRIPTION OF THE INVENTION

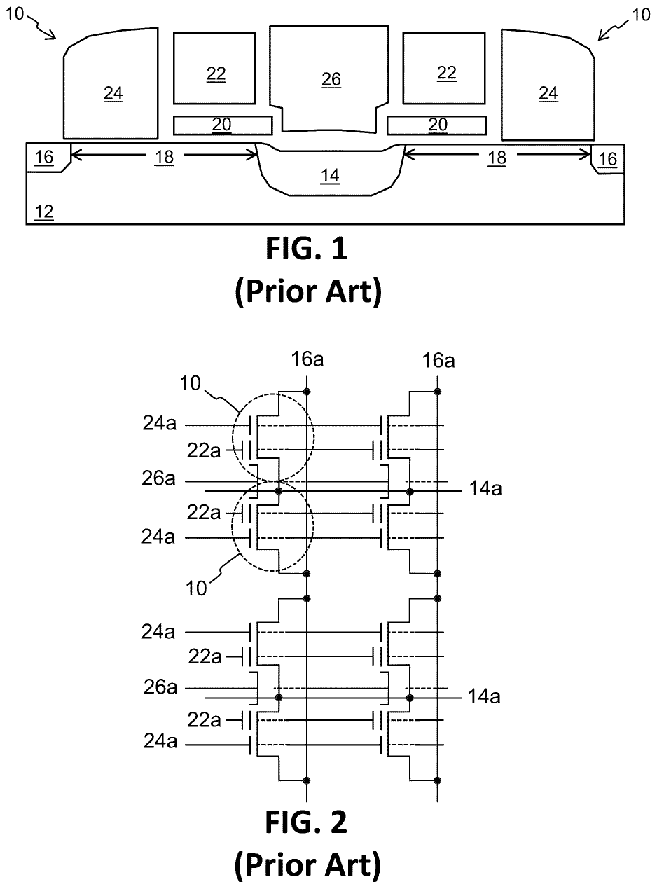

The present examples illustrate semiconductor devices and methods for addressing charge loss in non-volatile memory cells. The methods can be implemented as part of control circuitry 46, which controls the various device elements for a memory array, which can be better understood from the architecture of an example semiconductor device 29 as illustrated in FIG. 8. The semiconductor device 29 includes an array 30 of the memory cells 10, which can be segregated into two separate planes (Plane A 32a and Plane B 32b). The memory cells 10 can be of the type shown in FIG. 1, 3, 5, or 7, arranged in a plurality of rows and columns in the semiconductor substrate 12 as illustrated in FIG. 2, 4 or 6, and thus formed on a single chip. Adjacent to the array 30 of memory cells 10 are an address decoder 34 (e.g., XDEC), source line drivers 36 (e.g., SLDRV), a column decoder 38 (e.g., YMUX), a high voltage row decoder 40 (e.g., HVDEC), a bit line controller 42 (e.g., BLINHCTL), a bit line voltage/current source 48 (e.g., BLDRC), and a charge pump 44 (e.g., CHRGPMP), which are used to decode addresses and supply the various voltages to the various gates and regions of the memory cells 10 during read, program, and erase operations for selected memory cells 10 of the array 30, under the control of the control circuitry 46. Sense amplifier blocks 50 (e.g., SABLK) contains circuitry for measuring the currents on the bit lines during a read operation and supplying current during a program operation. Control circuitry 46 controls the various device elements to implement each operation (program, erase, read) on selected memory cells 10 of the array 30 as described herein. Control circuitry 46 operates the semiconductor device to program, erase and read the selected memory cells 10 of the array 30. As part of these operations, the control circuitry 46 can be provided with access to incoming data which is user data to be programmed to the selected memory cells 10 of the array 30, along with program, erase and read commands provided on the same or different lines. Data read from the array 30 (i.e., from selected memory cells 10 of the array 30) is provided as outgoing data.

The method involves the control circuitry 46 implementing program operations. Thus, control circuitry 46 may be loaded with software, i.e. non-transitory electronically readable instructions, or firmware, or can consist of respective circuits, or any combination thereof, to perform the methods described herein. Control circuitry 46 may be implemented by a microcontroller, dedicated circuitry, a processor, a general purpose processor running firmware or software, or a combination thereof.

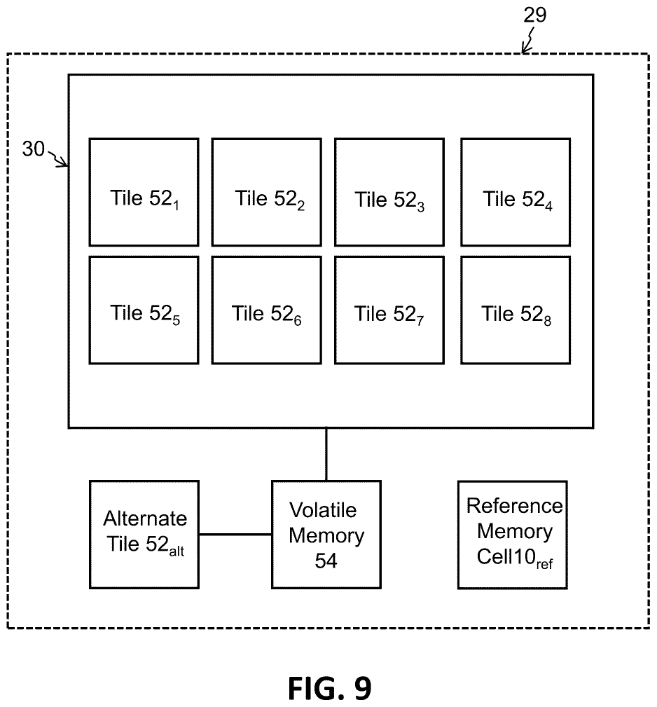

FIG. 9 illustrates additional details of the semiconductor device 29. The array 30 can be divided into a plurality of tiles 52. Each tile 52 includes a different group of the memory cells 10 of the array 30. As a non-limiting example, each tile 52 can include enough of the memory cells 10 of the array 30 to store Kbits, Mbits or tens of Mbits of data. For illustrative purposes, eight tiles 52 (52₁ to 52₈) are shown in FIG. 9, however, the number of tiles 52 in the array 30 can be any number greater than one. The semiconductor device 29 can further include a volatile memory 54, an alternative tile 52ₐₗₜ, and a reference memory cell 10_{ref}. Volatile memory includes memory cells that lose their data when the supply of power is turned off or interrupted. Examples of volatile memory 54 can include SRAM or DRAM. The alternative tile 52ₐₗₜ can include the same number of memory cells 10 as in each of the tiles 52. The alternative tile 52ₐₗₜ can be included as part of memory array 30, or can be in a separate memory array as shown in FIG. 9. The reference memory cell 10_{ref} can have the same configuration as memory cells 10. The reference memory cell 10_{ref} can be programmed to a target program state, whereby a read operation on the reference memory cell 10_{ref} yields a reference read current I_{ref} or a reference threshold voltage V_{thref} (which correspond to the target program state).

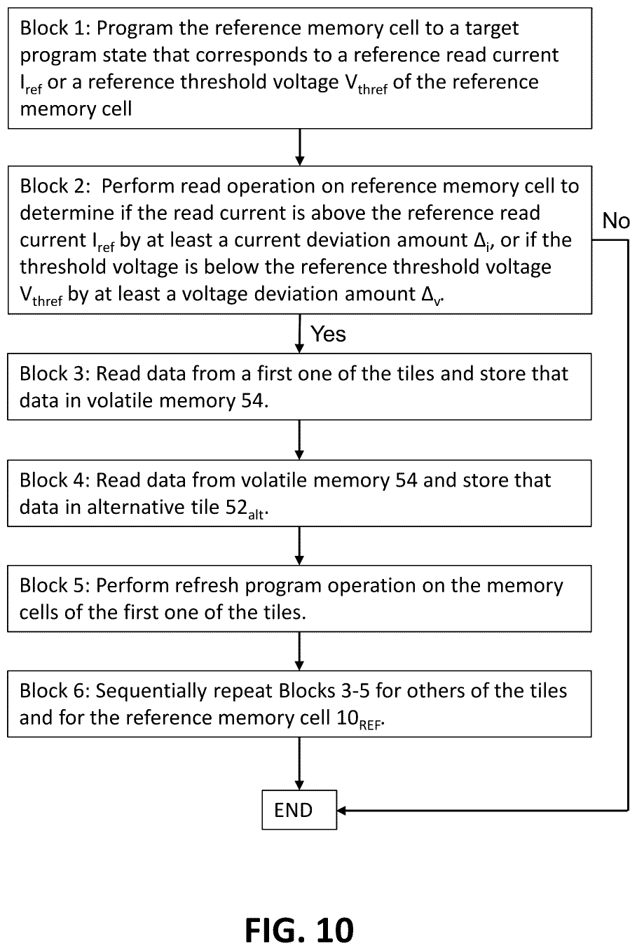

FIG. 10 illustrates the method of refreshing the program states of the memory cells 10 in the array 30. At Block 1, the reference memory cell 10_{ref} is programmed to a target program state that corresponds to the reference read current I_{ref} or the reference threshold voltage V_{thref} of the reference memory cell 10_{ref}. At Block 2, a read operation of the reference memory cell 10_{ref} is performed to determine if the read current Ir of the reference memory cell 10_{ref} is above the reference read current I_{ref} by at least a current deviation amount Δᵢ, or the threshold voltage of the reference memory cell 10_{ref} is below the reference threshold voltage V_{thref} by at least a voltage deviation amount Δᵥ. The current deviation amount Δᵢ can represent enough deviation from the reference read current I_{ref}, and/or the voltage deviation amount Δᵥ can represent enough deviation from the reference threshold voltage V_{thref}, to indicate enough downward program state drift has occurred to reference memory cell 10_{ref} to warrant refresh programming of the memory cells 10.

If the answer at Block 2 is no, then the process can end. If the answer at Block 2 is yes, that would indicate that the reference memory cell 10_{ref}, and therefore the memory cells 10 of the array 30, have experienced significant charge loss (i.e., resulting in a drop of the respective program states of the memory cells). A refresh programming can be performed in response to a yes determination to correct for the charge loss. The refresh programming begins at Block 3 by reading the data stored in a first one of the tiles (e.g., tile 52₁) and storing that data in volatile memory 54. This process may include the use of a multilevel cell sense amplifier to read the data in the tile for storage in volatile memory 54. At Block 4, the data stored in volatile memory 54 is read from volatile memory 54 and stored (i.e., programmed) into alternative tile 52ₐₗₜ. At Block 5, a refresh program operation is performed on the memory cells 10 of tile 52₁. The refresh program operation involves applying one or more pulses of program voltages on the memory cells 10 of tile 52₁, to increase the respective program states of the memory cells 10 by amounts that may approximate the charge loss indicated by the charge loss detected by the reference memory cell 10_{ref} in Block 2. Specifically, the amount of programming at Block 5 can correspond to the amount of programming that would in general reduce the respective read currents of the memory cells 10 by approximately current deviation amount Δᵢ, or that would in general increase the respective threshold voltages of the memory cells 10 by approximately voltage deviation amount Δᵥ. At Block 6, the process of Blocks 3-5 are sequentially repeated for the others of the tiles (i.e., tiles 52₂-52₈) and for the reference memory cell 10_{ref}. Once the method has ended, it can be repeated again, even periodically, starting at Block 1 or at Block 2.

The above described program refresh method has many advantages. First, it uses a reference memory cell 10_{ref} to detect charge loss, which can be typical of the charge loss incurred by the memory cells 10 in array 30. This avoids the need to read all the memory cells 10 in a tile and perform error detection/correction based on the read data to determine if charge loss has occurred. Second, for each tile 52, the method reads out and stores the data in the alternative tile 52ₐₗₜ before refresh programming is performed on the tile 52. While the refresh programming is being performed on any given tile 52, its data can be accessed from the alternative tile 52ₐₗₜ. This means that data stored in array 30 is fully accessible at any given time, even while one of the tiles is inaccessible because it is undergoing refresh programming. Specifically, the data can be read from the alternative tile 52ₐₗₜ concurrently with the application of the one or more pulses of programming voltages of the refresh program operation. This is important for applications that continuously access the array 30, whereby the operation of the application is not interrupted by refresh programming. Rather, refresh programming is a background operation that does not interfere with read operations on the data stored the array 30. While any given tile is undergoing refresh programming, read requests for data stored in that tile can be rerouted by the control circuitry 46 so the requested data is retrieved from a copy of the data temporarily stored in the alternative tile 52ₐₗₜ. Third, data from any given tile can be first stored in volatile memory 54 to speed up the data retrieval from the tile, because the write operation for volatile memory can be much faster that the program operation for non-volatile memory (i.e., the speed of the write operation for volatile memory better matches the speed of the read operation for non-volatile memory cells in the tile). This allows Block 5 to begin once Block 3 is completed (i.e., Blocks 4 and 5 can be performed concurrently, whereby refresh programming on a given tile can begin once its data is stored in volatile memory 54 even before the data is stored in the alternative tile 52ₐₗₜ, which means that the storing of the data in the alternative tile 52ₐₗₜ and the applying the one or more pulses of programming voltages to the corresponding one of the plurality of tiles can be performed concurrently). Fourth, a refresh program operation can be performed on the reference memory cells 10_{ref}, so that the same parameters in Block 2 can be used to detect future charge loss without starting over at Block 1. Finally, the refresh programming of the memory cells incrementally increases their respective program states (i.e., by approximately the amount of program state drop due to the charge loss indicated by the drop of the program state of the reference memory cell 10_{ref}), to effectively compensate for and correct for charge loss that generally occurs to the memory cells 10 across the array 30. Periodically performing refresh programming when charge loss is detected can prolong and enhance the accuracy of long term storage of data in array 30. This can be critically important for analog applications such as neural networks, which rely on the long term accuracy of weights stored in the memory cells 10 of array 30.

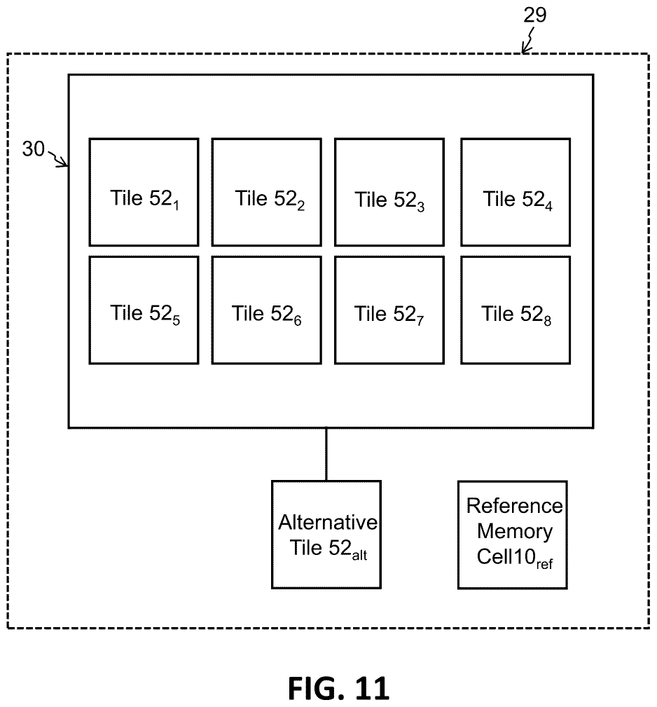

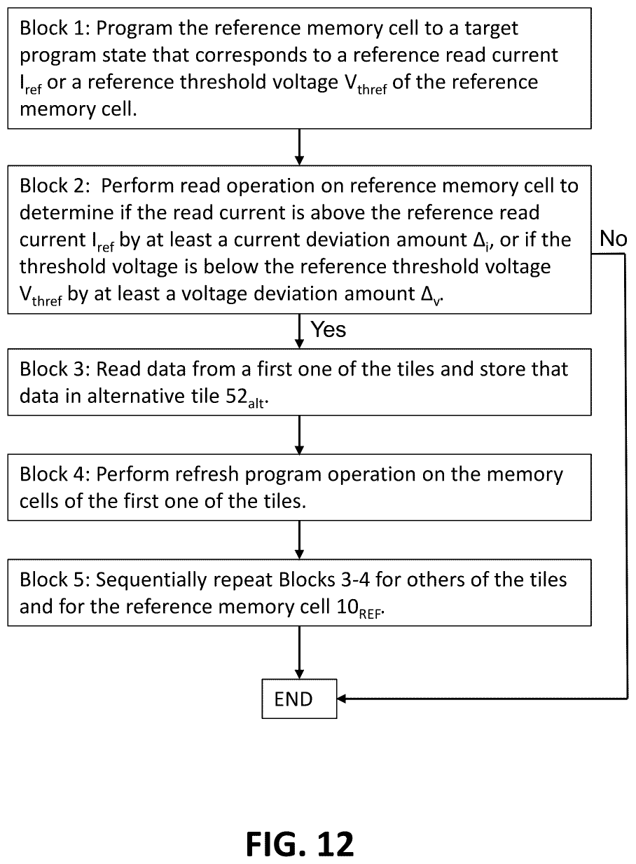

FIGS. 11-12 illustrate another example, which is the same as the example of FIGS. 9-10 except that volatile memory 54 is omitted, and the data read from the tiles 52 is stored directly in the alternative tile 52ₐₗₜ without any intervening storage in a volatile memory.

While the above examples utilize a single reference memory cell 10_{ref}, a plurality of reference memory cells 10_{ref} can be used in Blocks 1-2 to determine if refresh programming should occur for the array 30. For example, multiple reference memory cells 10_{ref} can be initially programmed to different program states between fully programmed and fully erased (reflecting the range of program states used to store the data in tiles 52). Performing the Block 2 read operation for the multiple reference memory cells 10_{ref} can provide information indicating that rates of charge loss may vary based on the program state levels of the memory cells. Therefore, considering multiple reference memory cells 10_{ref} as part of the Block 2 determination can provide better current deviation amount Δⱼ and voltage deviation amount Δᵥ criteria by which to trigger refresh programming. Using multiple reference memory cells can also provide more accuracy by averaging the results over many reference memory cells that themselves can vary in terms in charge loss (even at the same program state).

In an alternative example, instead of using one or more reference memory cells to trigger refresh programming in Block 2, the performance of an application using array 30 (e.g., the performance of a neural network using array 30) can be compared to a standard, and refresh programming can be triggered when the performance drops below a target specification or performance (i.e., given the assumption that the performance drop of the application is a result of charge loss).

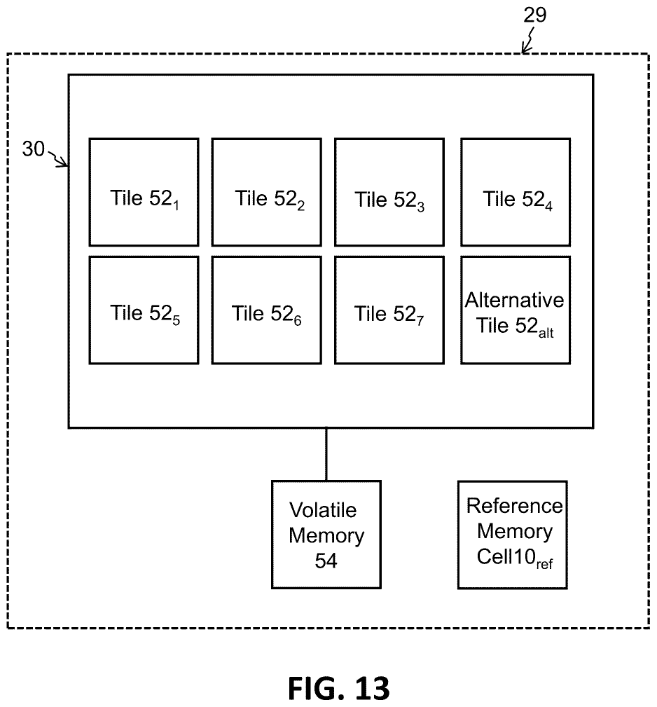

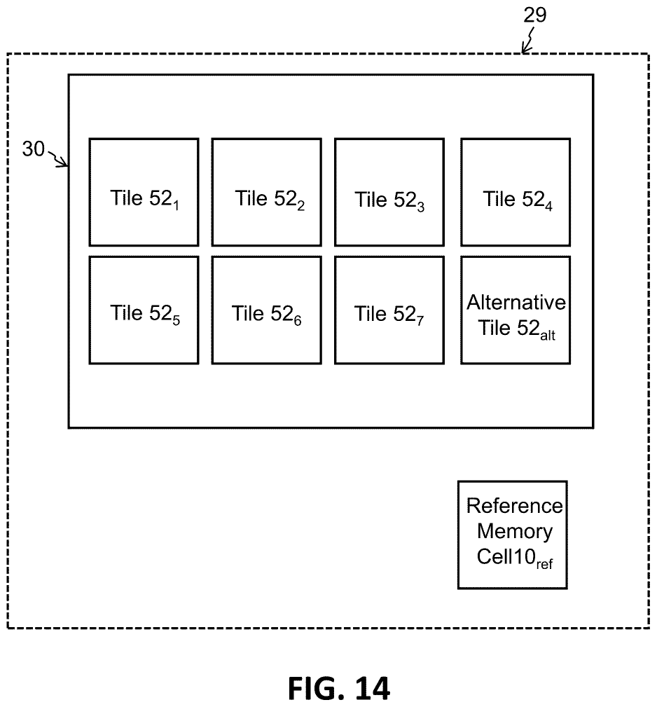

FIGS. 13 and 14 are additional examples which are the same as those of FIGS. 9 and 11 respectively, except that the alternative tile 52ₐₗₜ is one of the tiles inside of array 30.

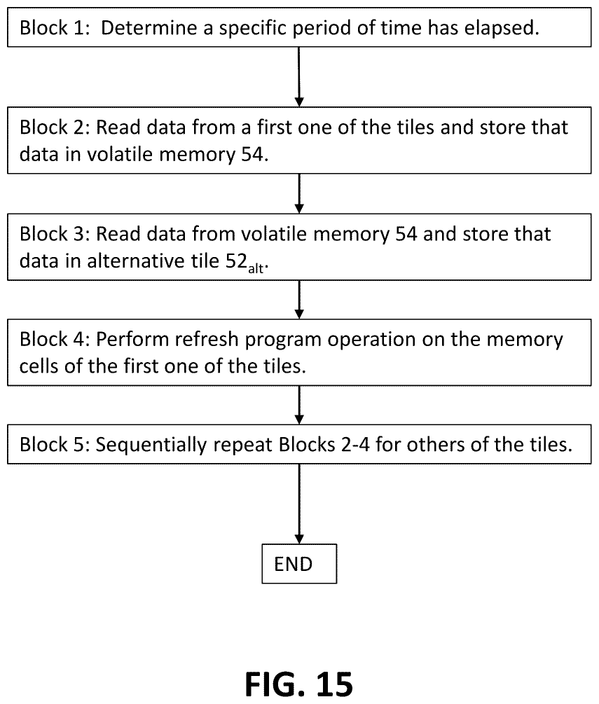

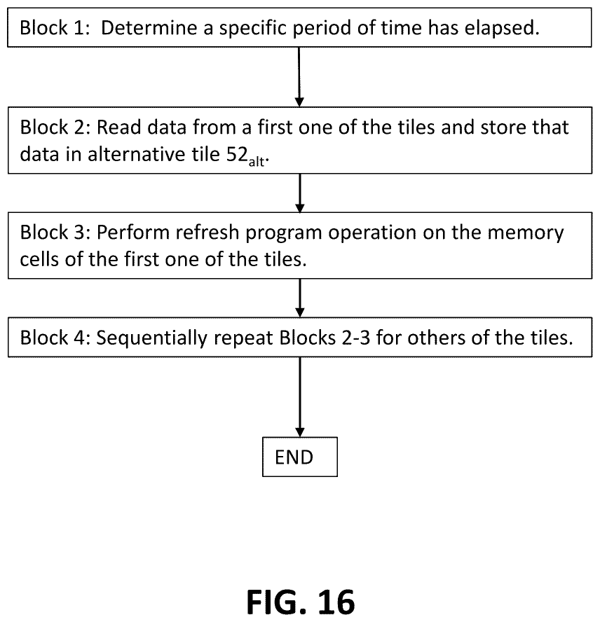

FIGS. 15 and 16 illustrate additional examples, which are similar to the examples of FIGS. 10 and 12 respectively, but Blocks 1 and 2 (involving programming and reading a reference memory cell to determine when refresh programming should be performed) are replaced with a Block 1 that determines refresh programming should be performed based upon a determination that a specific period of time has elapsed. Block 1 can be performed by the control circuitry 46 by using internal clock circuitry and/or rely on external clock or date information to measure elapsed time. For certain semiconductor devices, the rate of charge loss can measured or approximated for a given memory array, and then used to determine a specific period of time after which refresh programming should be performed. While this technique may not have the precision of using actual read operation measurements from a reference memory cell in the semiconductor device 29, it can suffice for those semiconductor devices 29 that exhibit predictable charge loss over time whether by design or by use, whereby read operations on a reference memory cell for determining when refresh programming should be performed, and the reference memory cell itself, can be omitted.

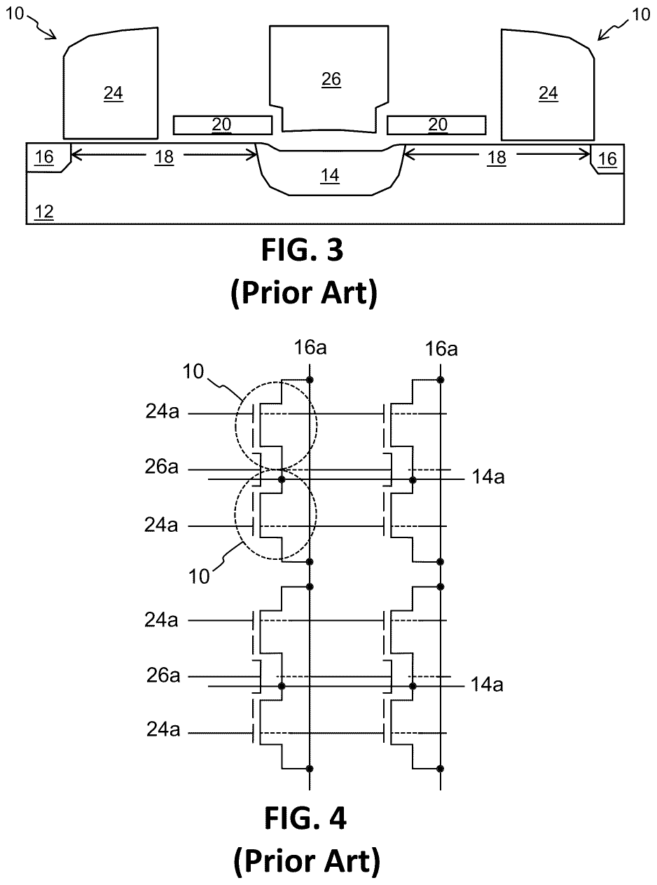

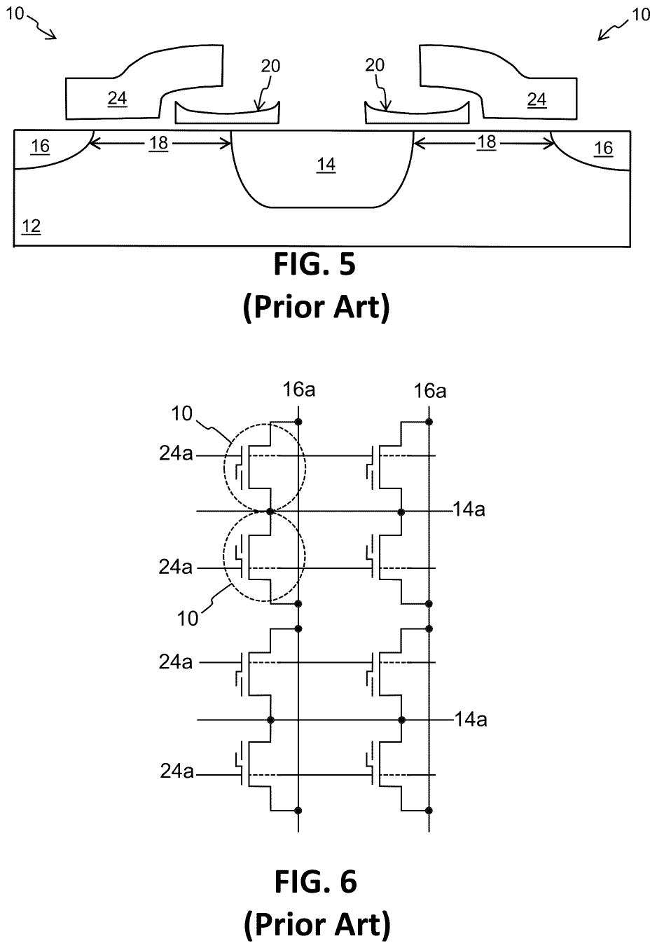

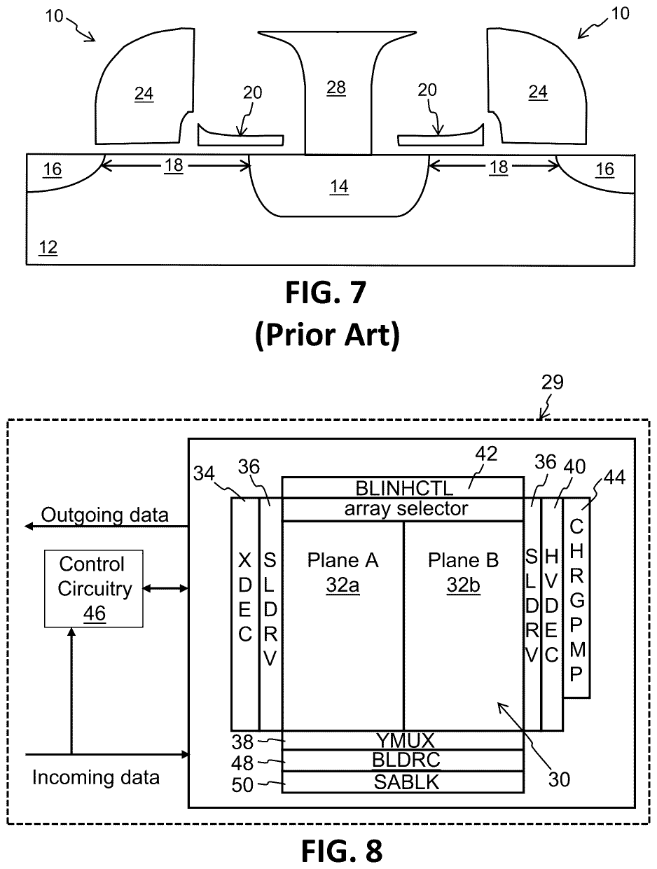

It is to be understood that the present disclosure is not limited to the example(s) described above and illustrated herein, but encompasses any and all variations falling within the scope of any claims. For example, while the above fast program techniques are described with respect to an array of the memory cells of FIG. 1, they are equally applicable to an array of the memory cells of FIG. 3, 5, or 7. References to the present disclosure or invention or examples herein are not intended to limit the scope of any claim or claim term, but instead merely make reference to one or more features that may be covered by one or more claims. Materials, processes and numerical examples described above are exemplary only, and should not be deemed to limit the claims. Further, as is apparent from the claims and specification, not all method operations need be performed in the exact order illustrated or claimed, but rather in any order (unless there is an explicitly recited limitation on any order). Single layers of material could be formed as multiple layers of such or similar materials, and vice versa. The terms “forming” and “formed” as used herein shall include material deposition, material growth, or any other technique in providing the material as disclosed or claimed. The claims are comprising claims unless otherwise stated, and therefore “each” of a plurality of elements having a limitation does not preclude the inclusion of additional such elements lacking the limitation unless otherwise specifically claimed. It should be noted that reference herein to circuitry, or a module of circuitry, or the like, to perform or configured to perform an operation refers to the physical structure of the circuit (i.e., the capabilities of the circuitry as dictated by its structure), and does not refer to any method or actual use of the circuitry.

What is claimed is:

1. A method of programming a semiconductor device that comprises:
a plurality of tiles of non-volatile memory cells;
an alternative tile of non-volatile memory cells; and
a reference memory cell;
the method comprising:
programming the reference memory cell to a target program state that corresponds to a reference read current of the reference memory cell or a reference threshold voltage of the reference memory cell;
determining through a read operation on the reference memory cell that a read current of the reference memory cell is above the reference read current by at least a current deviation amount or that a threshold voltage of the reference memory cell is below the reference threshold voltage by at least a voltage deviation amount;
in response to the determining, reading first data from a first one of the plurality of tiles of non-volatile memory cells;
storing the first data in the alternative tile of non-volatile memory cells; and
applying one or more pulses of programming voltages to the first one of the plurality of tiles of non-volatile memory cells.

2. The method of claim 1, comprising:
in response to the determining, reading second data from a second one of the plurality of tiles of non-volatile memory cells;
storing the second data in the alternative tile of non-volatile memory cells; and
applying one or more pulses of programming voltages to the second one of the plurality of tiles of non-volatile memory cells.

3. The method of claim 1, comprising:
in response to the determining, applying one or more pulses of programming voltages to the reference memory cell.

4. The method of claim 1, comprising:
reading the first data from the alternative tile of non-volatile memory cells concurrently with the applying the one or more pulses of programming voltages to the first one of the plurality of tiles of non-volatile memory cells.

5. The method of claim 2, comprising:
reading the second data from the alternative tile of non-volatile memory cells concurrently with the applying the one or more pulses of programming voltages to the second one of the plurality of tiles of non-volatile memory cells.

6. The method of claim 1, wherein:
the semiconductor device comprises volatile memory; and
the method comprises storing the first data in the volatile memory before the storing the first data in the alternative tile of non-volatile memory cells.

7. The method of claim 6, wherein the storing of the first data in the alternative tile of non-volatile memory cells and the applying the one or more pulses of programming voltages to the first one of the plurality of tiles of non-volatile memory cells are performed concurrently.

8. A semiconductor device comprising:
a plurality of tiles of non-volatile memory cells;
an alternative tile of non-volatile memory cells;
a reference memory cell; and
a control circuitry to:
program the reference memory cell to a target program state that corresponds to a reference read current of the reference memory cell or a reference threshold voltage of the reference memory cell;
determine through a read operation on the reference memory cell that a read current of the reference memory cell is above the reference read current by at least a current deviation amount or that a threshold voltage of the reference memory cell is below the reference threshold voltage by at least a voltage deviation amount;
in response to the determination, read first data from a first one of the plurality of tiles of non-volatile memory cells;
store the first data in the alternative tile of non-volatile memory cells; and
apply one or more pulses of programming voltages to the first one of the plurality of tiles of non-volatile memory cells.

9. The semiconductor device of claim 8, wherein the control circuitry is to:
in response to the determining, read second data from a second one of the plurality of tiles of non-volatile memory cells;
store the second data in the alternative tile of non-volatile memory cells; and
apply one or more pulses of programming voltages to the second one of the plurality of tiles of non-volatile memory cells.

10. The semiconductor device of claim 8, wherein the control circuitry is to:
in response to the determining, apply one or more pulses of programming voltages to the reference memory cell.

11. The semiconductor device of claim 8, wherein the control circuitry is to:
read the first data from the alternative tile of non-volatile memory cells concurrently with the application of the one or more pulses of programming voltages to the first one of the plurality of tiles of non-volatile memory cells.

12. The semiconductor device of claim 9, wherein the control circuitry is to:
read the second data from the alternative tile of non-volatile memory cells concurrently with the application of the one or more pulses of programming voltages to the second one of the plurality of tiles of non-volatile memory cells.

13. The semiconductor device of claim 8, comprising:
volatile memory, wherein the control circuitry is to store the first data in the volatile memory before the storage of the first data in the alternative tile of non-volatile memory cells.

14. The semiconductor device of claim 13, wherein the control circuitry is to perform concurrently the storage of the first data in the alternative tile of non-volatile memory cells and the application of the one or more pulses of programming voltages to the first one of the plurality of tiles of non-volatile memory cells.

15. A method of programming a semiconductor device that comprises a plurality of tiles of non-volatile memory cells and an alternative tile of non-volatile memory cells, the method comprising:
determining a specific period of time has elapsed;
in response to the determining, reading first data from a first one of the plurality of tiles of non-volatile memory cells;
storing the first data in the alternative tile of non-volatile memory cells; and
applying one or more pulses of programming voltages to the first one of the plurality of tiles of non-volatile memory cells.

16. The method of claim 15, comprising:
in response to the determining, reading second data from a second one of the plurality of tiles of non-volatile memory cells;
storing the second data in the alternative tile of non-volatile memory cells; and
applying one or more pulses of programming voltages to the second one of the plurality of tiles of non-volatile memory cells.

17. The method of claim 15, comprising:
reading the first data from the alternative tile of non-volatile memory cells concurrently with the applying the one or more pulses of programming voltages to the first one of the plurality of tiles of non-volatile memory cells.

18. The method of claim 16, comprising:
reading the second data from the alternative tile of non-volatile memory cells concurrently with the applying the one or more pulses of programming voltages to the second one of the plurality of tiles of non-volatile memory cells.

19. The method of claim 15, wherein:
the semiconductor device comprises volatile memory; and
the method comprises storing the first data in the volatile memory before the storing the first data in the alternative tile of non-volatile memory cells.

20. The method of claim 19, wherein the storing of the first data in the alternative tile of non-volatile memory cells and the applying the one or more pulses of programming voltages to the first one of the plurality of tiles of non-volatile memory cells are performed concurrently.

21. A semiconductor device comprising:
a plurality of tiles of non-volatile memory cells;
an alternative tile of non-volatile memory cells; and
a control circuitry to:
determine a specific period of time has elapsed;
in response to the determination, read first data from a first one of the plurality of tiles of non-volatile memory cells;
store the first data in the alternative tile of non-volatile memory cells; and
apply one or more pulses of programming voltages to the first one of the plurality of tiles of non-volatile memory cells.

22. The semiconductor device of claim 21, wherein the control circuitry is to:
in response to the determining, read second data from a second one of the plurality of tiles of non-volatile memory cells;
store the second data in the alternative tile of non-volatile memory cells; and
apply one or more pulses of programming voltages to the second one of the plurality of tiles of non-volatile memory cells.

23. The semiconductor device of claim 21, wherein the control circuitry is to:
read the first data from the alternative tile of non-volatile memory cells concurrently with the application of the one or more pulses of programming voltages to the first one of the plurality of tiles of non-volatile memory cells.

24. The semiconductor device of claim 22, wherein the control circuitry is to:
read the second data from the alternative tile of non-volatile memory cells concurrently with the application of the one or more pulses of programming voltages to the second one of the plurality of tiles of non-volatile memory cells.

25. The semiconductor device of claim 21, comprising:
volatile memory, wherein the control circuitry is to store the first data in the volatile memory before the storage of the first data in the alternative tile of non-volatile memory cells.

26. The semiconductor device of claim 25, wherein the control circuitry is to perform concurrently the storage of the first data in the alternative tile of non-volatile memory cells and the application of the one or more pulses of programming voltages to the first one of the plurality of tiles of non-volatile memory cells.
